(19) United States
(12) Patent Application Publication
(10) Pub. No.: US 2025/0380452 A1
(43) Pub. Date: Dec. 11, 2025

(54) SHAPED EPITAXY

(71) Applicant: International Business Machines Corporation, Armonk, NY (US)

(72) Inventors: Jay William Strane, Wappingers Falls, NY (US); Shay Reboh, Albany, NY (US); Shogo Mochizuki, Mechanicville, NY (US); Tsung-Sheng Kang, Ballston Lake, NY (US); Matthew Malley, Averill Park, NY (US); Junli Wang, Slingerlands, NY (US)

(21) Appl. No.: 18/734,283

(22) Filed: Jun. 5, 2024

(51) Int. Cl. H01L 29/786; H01L 21/306; H01L 27/088; H01L 29/06; H01L 29/66; H01L 29/423; H01L 29/775

(52) U.S. Cl. CPC H10D 30/6713; H01L 21/30625; H10D 30/014; H10D 30/43; H10D 30/6735; H10D 30/6757; H10D 62/121; H10D 64/018; H10D 84/83

(57) ABSTRACT

A semiconductor device is provided and includes a semiconductor substrate, a first nanosheet field effect transistor (FET) disposed on the semiconductor substrate, a second nanosheet FET stacked on the first nanosheet FET, dielectric material vertically interposed between the first nanosheet FET and the second nanosheet FET, bottom source/drain (S/D) epitaxy and top S/D epitaxy. The bottom S/D epitaxy contacts nanosheets of the first nanosheet FET. The bottom S/D epitaxy is formed from depositional overgrowth, chemical mechanical polishing (CMP) and recession processes and thereby includes a flat upper surface coplanar with a portion of the dielectric material. The top S/D epitaxy contacts nanosheets of the second nanosheet FET. The top S/D epitaxy is grown to have a shape differing from a shape of the bottom S/D epitaxy.

### BACKGROUND

The present disclosure generally relates to fabrication methods and resulting structures for semiconductor devices. More specifically, the present disclosure relates to obtaining shaped epitaxy in semiconductor devices.

As the semiconductor industry moves towards smaller nodes, for example 7-nm nodes and beyond, field-effect-transistors (FETs) are being aggressively scaled in order to fit into the reduced footprint or real estate, as defined by the node, with increased device density. Among various types of FETs, non-planar FETs such as nanosheet FETs and stacked nanosheet FETs are being developed to meet continued device scaling needs.

A nanosheet FET generally has a channel region that includes one or more elongated semiconductor layers in a stacked configuration. Each semiconductor layer is known as a nanosheet layer (or a nanosheet channel). In a nanosheet FET, gate material is generally formed to surround all sides of each of the stacked nanosheet layers and therefore a nanosheet FET may also be referred to as a gate-all-around (GAA) FET or a GAA nanosheet FET. Source and drain (S/D) regions of the nanosheet FET are formed at the two ends of the nanosheet layers and access to the S/D regions is made through metal contacts formed above the S/D regions.

A stacked nanosheet FET is a structure in which two nanosheet transistors are stacked together.

### SUMMARY

According to an aspect of the disclosure, a semiconductor device is provided and includes a semiconductor substrate, a first nanosheet field effect transistor (FET) disposed on the semiconductor substrate, a second nanosheet FET stacked on the first nanosheet FET, dielectric material vertically interposed between the first nanosheet FET and the second nanosheet FET, bottom source/drain (S/D) epitaxy and top S/D epitaxy. The bottom S/D epitaxy contacts nanosheets of the first nanosheet FET. The bottom S/D epitaxy is formed from depositional overgrowth, chemical mechanical polishing (CMP) and recession processes and thereby includes a flat upper surface coplanar with a portion of the dielectric material. The top S/D epitaxy contacts nanosheets of the second nanosheet FET. The top S/D epitaxy is grown to have a shape differing from a shape of the bottom S/D epitaxy. In additional or alternative embodiments, the semiconductor device provides for at least bottom S/D epitaxy with controlled shapes.

According to an aspect of the disclosure, a semiconductor device is provided and includes a semiconductor substrate, shallow trench isolation (STI) disposed in the semiconductor substrate and first and second stacked nanosheet field effect transistors (FETs) at opposite sides of the STI. Each of the first and second stacked nanosheet FETs includes a first nanosheet FET disposed on the semiconductor substrate, a second nanosheet FET stacked on the first nanosheet FET, dielectric material vertically interposed between the first nanosheet FET and the second nanosheet FET, bottom source/drain (S/D) epitaxy and top S/D epitaxy. The bottom S/D epitaxy contacts nanosheets of the first nanosheet FET. The bottom S/D epitaxy is formed from depositional overgrowth, chemical mechanical polishing (CMP) and recession processes and thereby includes a flat upper surface coplanar with a portion of the dielectric material. The top S/D epitaxy contacts nanosheets of the second nanosheet FET. The top S/D epitaxy is grown to have a shape differing from a shape of the bottom S/D epitaxy. The top S/D epitaxy is grown to have a shape differing from a shape of the bottom S/D epitaxy. In additional or alternative embodiments, the semiconductor device provides for at least bottom S/D epitaxy with controlled shapes.

According to an aspect of the disclosure, a method of fabricating a semiconductor device is provided and includes building a stacked nanosheet field effect transistor (FET) including a first nanosheet FET, a second nanosheet FET stacked on the first nanosheet FET, dielectric material vertically interposed between the first and second nanosheet FETs and inner spacers through which nanosheets of the first nanosheet FET are exposed, forming bottom source/drain (S/D) epitaxy from depositional overgrowth to contact the nanosheets of the first nanosheet FET, executing chemical mechanical polishing (CMP) of the bottom S/D epitaxy to a height which exceeds a height of a hard mask disposed over the second nanosheet FET, recessing the bottom S/D epitaxy to include a flat upper surface coplanar with a portion of the dielectric material and forming top S/D epitaxy contacting nanosheets of the second nanosheet FET, the top S/D epitaxy being grown to have a shape differing from a shape of the bottom S/D epitaxy. In additional or alternative embodiments, the method of fabricating the semiconductor device provides for at least bottom S/D epitaxy with controlled shapes.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a flow diagram illustrating a method of fabricating a semiconductor device in accordance with one or more embodiments;

FIG. 2 is a top view of a semiconductor device in accordance with one or more embodiments;

FIG. 3 is a side view of a semiconductor device structure in an initial fabrication stage taken along line 2-2 of FIG. 2 in accordance with one or more embodiments;

FIG. 4 is a side view of a semiconductor device structure in a secondary fabrication stage taken along line 2-2 of FIG. 2 in accordance with one or more embodiments;

FIG. 5 is a side view of a semiconductor device structure in a tertiary fabrication stage taken along line 2-2 of FIG. 2 in accordance with one or more embodiments;

FIG. 6 is a side view of a semiconductor device structure in a fourth fabrication stage taken along line 2-2 of FIG. 2 in accordance with one or more embodiments;

FIG. 7 is a side view of a semiconductor device structure in a fifth fabrication stage taken along line 2-2 of FIG. 2 in accordance with one or more embodiments;

FIG. 8 is a side view of a semiconductor device including stacked nanosheet FETs in accordance with one or more embodiments; and

FIG. 9 is a schematic view of a semiconductor device in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided and includes a semiconductor substrate, a first nanosheet field effect transistor (FET) disposed on the semiconductor substrate, a second nanosheet FET stacked on the first nanosheet FET, dielectric material vertically interposed between the first nanosheet FET and the second nanosheet FET, bottom source/drain (S/D) epitaxy and top S/D epitaxy. The bottom S/D epitaxy contacts nanosheets of the first nanosheet FET. The bottom S/D epitaxy is formed from depositional overgrowth, chemical mechanical polishing (CMP) and recession processes and thereby includes a flat upper surface coplanar with a portion of the dielectric material. The top S/D epitaxy contacts nanosheets of the second nanosheet FET. The top S/D epitaxy is grown to have a shape differing from a shape of the bottom S/D epitaxy. In additional or alternative embodiments, the semiconductor device provides for at least bottom S/D epitaxy with controlled shapes.

The first nanosheet FET includes inner spacers through which the nanosheets are exposed to contact the bottom S/D epitaxy. The bottom S/D epitaxy would normally be grown from the inner spacers but instead it is depositionally overgrown instead to provide for the formation of bottom S/D epitaxy with controlled shapes.

Dielectric liner material and additional dielectric material are disposed on the flat upper surface of the bottom S/D epitaxy to separate the bottom S/D epitaxy from the top S/D epitaxy.

The dielectric material, the dielectric liner material and the additional dielectric material differ from one another to facilitate lithographic processing.

The bottom S/D epitaxy is rectangular and the top S/D epitaxy is non-rectangular. The rectangular bottom epitaxy provides for a controlled shape which leads to improvements in terms of process and device characteristic variations being reduced especially in cases of stacked nanosheet FETs.

A side of the bottom S/D epitaxy is vertical and defines a vertical plane and a side of the top S/D epitaxy, which corresponds to the side of the bottom S/D epitaxy, protrudes beyond the vertical plane. At least the vertical side provides for increased circuit density.

The bottom S/D epitaxy is wider than a width of the nanosheets of the first nanosheet FET and has a small epitaxy overburden to improve and reduce electrical resistance.

The bottom S/D epitaxy includes the flat upper surface and a chamfered surface forming an obtuse angle with the flat upper surface and the semiconductor device further includes a wrap-around contact disposed in contact with the flat upper surface and the chamfered surface to improve and reduce electrical resistance.

According to an aspect of the disclosure, a semiconductor device is provided and includes a semiconductor substrate, shallow trench isolation (STI) disposed in the semiconductor substrate and first and second stacked nanosheet field effect transistors (FETs) at opposite sides of the STI. Each of the first and second stacked nanosheet FETs includes a first nanosheet FET disposed on the semiconductor substrate, a second nanosheet FET stacked on the first nanosheet FET, dielectric material vertically interposed between the first nanosheet FET and the second nanosheet FET, bottom source/drain (S/D) epitaxy and top S/D epitaxy. The bottom S/D epitaxy contacts nanosheets of the first nanosheet FET. The bottom S/D epitaxy is formed from depositional overgrowth, chemical mechanical polishing (CMP) and recession processes and thereby includes a flat upper surface coplanar with a portion of the dielectric material. The top S/D epitaxy contacts nanosheets of the second nanosheet FET. The top S/D epitaxy is grown to have a shape differing from a shape of the bottom S/D epitaxy. The top S/D epitaxy is grown to have a shape differing from a shape of the bottom S/D epitaxy. In additional or alternative embodiments, the semiconductor device provides for at least bottom S/D epitaxy with controlled shapes.

The first nanosheet FET of each of the first and second stacked nanosheet FETs includes inner spacers through which the nanosheets of the first nanosheet FET are exposed to contact the bottom S/D epitaxy. The bottom S/D epitaxy would normally be grown from the inner spacers but instead it is depositionally overgrown instead to provide for the formation of bottom S/D epitaxy with controlled shapes.

Dielectric liner material and additional dielectric material are disposed on the flat upper surface of the bottom S/D epitaxy of each of the first and second stacked nanosheet FETs to separate the bottom S/D epitaxy from the top S/D epitaxy of each of the first and second stacked nanosheet FETs.

For each of the first and second stacked nanosheet FETs, the dielectric material, the dielectric liner material and the additional dielectric material differ from one another to facilitate lithographic processing.

The bottom S/D epitaxy is rectangular and the top S/D epitaxy is non-rectangular for each of the first and second stacked nanosheet FETs. The rectangular bottom epitaxy provides for a controlled shape which leads to improvements in terms of process and device characteristic variations being reduced especially in cases of stacked nanosheet FETs.

For each of the first and second stacked nanosheet FETs, a side of the bottom S/D epitaxy is vertical and defines a vertical plane extending upwardly from the STI. At least the vertical side provides for increased circuit density.

For each of the first and second stacked nanosheet FETs, the bottom S/D epitaxy is wider than a width of the nanosheets of the first nanosheet FET and has a small epitaxy overburden to improve and reduce electrical resistance.

For each of the first and second stacked nanosheet FETs, the bottom S/D epitaxy includes the flat upper surface and a chamfered surface remote from the STI and forming an obtuse angle with the flat upper surface and the semiconductor device further includes a wrap-around contact disposed in contact with the flat upper surface and the chamfered surface to improve and reduce electrical resistance.

According to an aspect of the disclosure, a method of fabricating a semiconductor device is provided and includes building a stacked nanosheet field effect transistor (FET) including a first nanosheet FET, a second nanosheet FET stacked on the first nanosheet FET, dielectric material vertically interposed between the first and second nanosheet FETs and inner spacers through which nanosheets of the first nanosheet FET are exposed, forming bottom source/drain (S/D) epitaxy from depositional overgrowth to contact the nanosheets of the first nanosheet FET, executing chemical mechanical polishing (CMP) of the bottom S/D epitaxy to a height which exceeds a height of a hard mask disposed over the second nanosheet FET, recessing the bottom S/D epitaxy to include a flat upper surface coplanar with a portion of the dielectric material and forming top S/D epitaxy contacting nanosheets of the second nanosheet FET, the top S/D epitaxy being grown to have a shape differing from a shape of the bottom S/D epitaxy. In additional or alternative embodiments, the method of fabricating the semiconductor device provides for at least bottom S/D epitaxy with controlled shapes.

The method further includes depositing dielectric liner material and additional dielectric material on the flat upper surface of the bottom S/D epitaxy and the dielectric material, the dielectric liner material and the additional dielectric material differ from one another to facilitate lithographic processing.

The bottom S/D epitaxy is rectangular and the top S/D epitaxy is non-rectangular. The rectangular bottom epitaxy provides for a controlled shape which leads to improvements in terms of process and device characteristic variations being reduced especially in cases of stacked nanosheet FETs.

The recessing of the bottom S/D epitaxy includes forming the flat upper surface and a chamfered surface forming an obtuse angle with the flat upper surface and the method further includes forming a wrap-around contact disposed in contact with the flat upper surface and the chamfered surface to improve and reduce electrical resistance.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, it has been found that S/D epitaxial growth in a nanosheet FET or a stacked nanosheet FET with inner spacers can be difficult to control. This is because the S/D epitaxy is typically grown from semiconductor material that is exposed through the inner spacers whereby the growth pattern can be unpredictable. The lack of control in S/D epitaxial growth can lead to S/D epitaxy that exhibits shape variation, which, in turn, can lead to process and device characteristic variation (i.e., capacitances, resistance, etc.).

Turning now to an overview of the aspects of the disclosure, one or more embodiments of the disclosure address the above-described shortcomings of the prior art by providing a method and a structure in which S/D epitaxial overgrowth is employed and followed by chemical mechanical polishing (CMP) processes and controlled recession to obtain S/D epitaxy with a controlled shape. This leads to improvements in terms of process and device characteristic variations (i.e., capacitances, resistance, etc.) being reduced especially in cases of stacked nanosheet FETs.

The above-described aspects of the disclosure address the shortcomings of the prior art by providing a semiconductor device that includes a semiconductor substrate, a first nanosheet FET disposed on the semiconductor substrate, a second nanosheet FET stacked on the first nanosheet FET, dielectric material vertically interposed between the first nanosheet FET and the second nanosheet FET and bottom and top S/D epitaxy. The bottom S/D epitaxy contacts nanosheets of the first nanosheet FET and is formed from depositional overgrowth, chemical mechanical polishing (CMP) and recession processes to thereby include a flat upper surface coplanar with a portion of the dielectric material. The top S/D epitaxy contacts nanosheets of the second nanosheet FET and is grown to have a shape differing from a shape of the bottom S/D epitaxy.

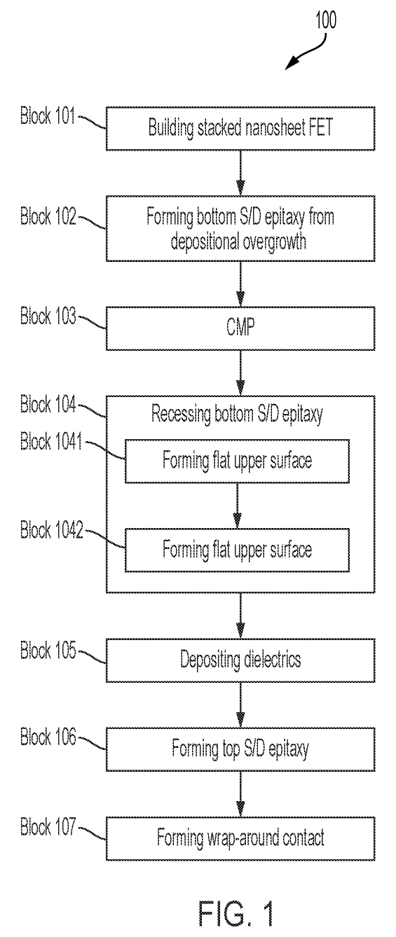

Turning now to a more detailed description of aspects of the present disclosure, FIG. 1 is a flow diagram illustrating a method 100 of fabricating a semiconductor device. The method 100 includes building a stacked nanosheet FET (block 101) to include a first nanosheet FET, a second nanosheet FET stacked on the first nanosheet FET, dielectric material vertically interposed between the first and second nanosheet FETs and inner spacers through which nanosheets of the first nanosheet FET are exposed. The method 100 further includes forming bottom S/D epitaxy from depositional overgrowth to contact the nanosheets of the first nanosheet FET (block 102).

The depositional overgrowth processes differ from the processes-of-record (POR) in that the POR generally involves growth of the bottom S/D epitaxy from portions of the nanosheets of the first nanosheet FET that are exposed through the inner spacers whereas the depositional overgrowth is a depositional process that does not involve epitaxial growth from the portions of the nanosheets of the first nanosheet FET. This depositional overgrowth continues until the bottom S/D epitaxy has a height that exceeds the height of an uppermost surface of a hard mask disposed over the second nanosheet FET by such an extent that troughs in the bottom S/D epitaxy are still higher than the uppermost surface of the hard mask.

Following the depositional overgrowth of block 102, the method 100 includes executing CMP of the bottom S/D epitaxy to a height which exceeds the height of the uppermost surface of the hard mask disposed over the second nanosheet FET (block 103), which is enabled by the depositional overgrowth continuing as described above, and recessing the bottom S/D epitaxy to include a flat upper surface that is coplanar with a portion of the dielectric material (block 104). The method 100 subsequently includes depositing dielectric liner material and additional dielectric material on the flat upper surface of the bottom S/D epitaxy (block 105), where the dielectric material, the dielectric liner material and the additional dielectric material can differ from one another, and forming top S/D epitaxy contacting nanosheets of the second nanosheet FET (block 106) where the top S/D epitaxy is grown to have a shape differing from a shape of the bottom S/D epitaxy.

Whereas the epitaxial growth of the POR involves the growth of the bottom S/D epitaxy from portions of the nanosheets of the first nanosheet FET that are exposed through the inner spacers and thus results in epitaxy of irregular, unpredictable and uncontrolled shapes, the depositional overgrowth of block 102, the CMP of block 103 and the recessing of block 104 provide for bottom S/D epitaxy that has a regular, predictable and controlled shape (i.e., such as a flat upper surface) onto which further layers can be deposited. Meanwhile, the forming of the top S/D epitaxy of block 105 can involve epitaxial growth from portions of nanosheets of the second nanosheet FET that are exposed through inner spaces of the second nanosheet FET and thus can result in top S/D epitaxy that differs in shape from the bottom S/D epitaxy.

In an exemplary case, the bottom S/D epitaxy can be rectangular and the top S/D epitaxy can be non-rectangular.

In accordance with one or more embodiments, the recessing of the bottom S/D epitaxy of block 104 can include forming the flat upper surface (block 1041) and forming a chamfered surface forming an obtuse angle with the flat upper surface (block 1042). In these or other cases, the method 100 can further include forming a wrap-around contact to be disposed in contact with the flat upper surface and the chamfered surface (block 107).

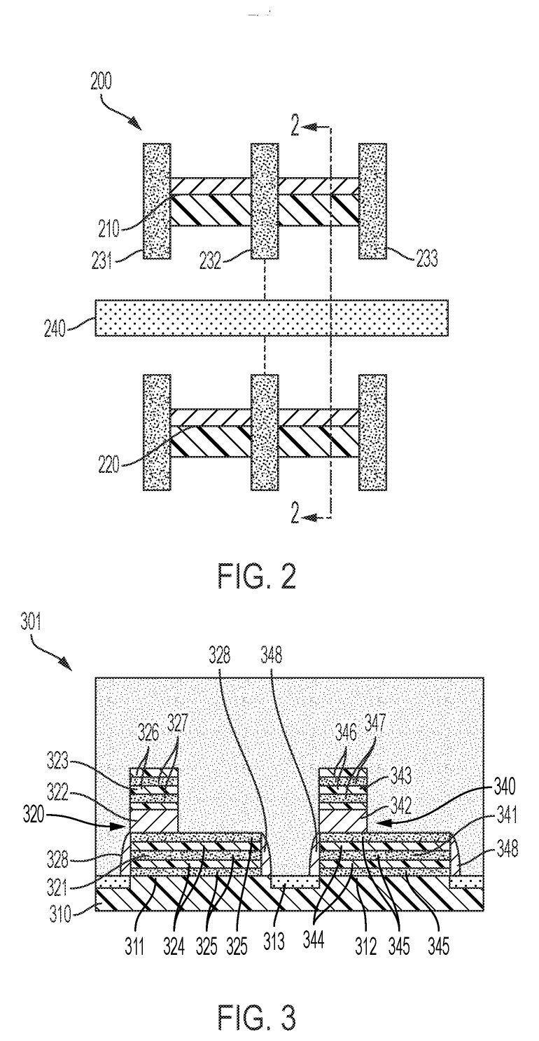

With reference to FIG. 2 and with additional reference to FIGS. 3-7, a semiconductor device 200 is provided and can be formed using the method 100 of FIG. 1 as described in further detail below. For this description, FIG. 2 is a top-down view of the semiconductor device 200 illustrating that the semiconductor device 200 can include first nanosheet channel 210, second nanosheet channel 220, first, second and third gates 231, 232, 233 that each cross the first nanosheet channel 210 and the second nanosheet channel 220 and bottom dielectric isolation (BDI) 240 interposed between the first nanosheet channel 210 and the second nanosheet channel 220. FIGS. 3-7 are cross-sectional views taken along the line 2-2 of FIG. 2.

As shown in FIG. 3, at an initial fabrication stage, a semiconductor device structure 301 is provided and includes a semiconductor substrate 310 that is formed to define first pillar 311 and second pillar 312 with BDI 313 interposed between the first pillar 311 and the second pillar 312. A first nanosheet channel region can be assembled on the first pillar 311 to include a first stacked nanosheet FET structure 320 and a second nanosheet channel region can be assembled on second pillar 312 to include a second stacked nanosheet FET structure 340. The first stacked nanosheet FET structure 320 includes a first nanosheet FET element 321 disposed on the first pillar 311, dielectric material 322 disposed on the first nanosheet FET element 321 and a second nanosheet FET element 323 disposed on the dielectric material 322. The second stacked nanosheet FET structure 340 includes a first nanosheet FET element 341 disposed on the second pillar 312, dielectric material 342 disposed on the first nanosheet FET element 341 and a second nanosheet FET element 343 disposed on the dielectric material 342.

For the first stacked nanosheet FET structure 320, the first nanosheet FET element 321 includes nanosheets 324 interleaved with dielectric material layers 325 and the second nanosheet FET element 323 includes nanosheets 326 interleaved with dielectric material layers 327. Inner spacers 328 are disposed on either side of the first nanosheet element 321.

For the second stacked nanosheet FET structure 340, the first nanosheet FET element 341 includes nanosheets 344 interleaved with dielectric material layers 345 and the second nanosheet FET element 343 includes nanosheets 346 interleaved with dielectric material layers 347. Inner spacers 348 are disposed on either side of the first nanosheet element 341.

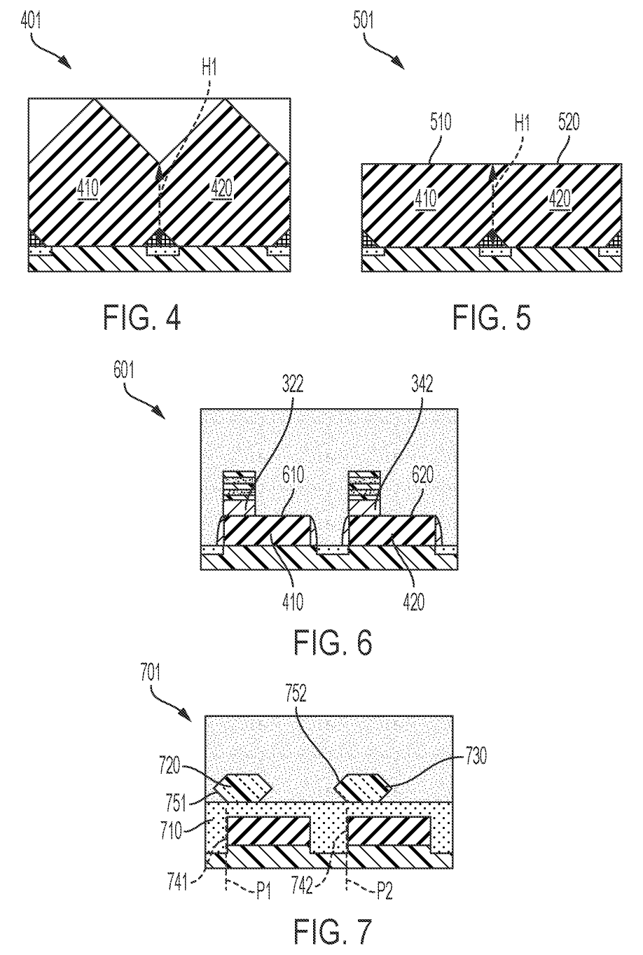

As shown in FIG. 4, at a secondary fabrication stage, a semiconductor device structure 401 is provided following depositional overgrowth of the bottom S/D epitaxy executed with respect to the semiconductor device structure 301 of FIG. 3. The semiconductor device structure 401 includes bottom S/D epitaxy 410 adjacent to the first stacked nanosheet FET structure 320 and bottom S/D epitaxy 420 adjacent to the second stacked nanosheet FET structure 340. The bottom S/D epitaxy 410 is disposed in contact with the nanosheets 324 of the first nanosheet FET element 321 and the bottom S/D epitaxy 420 is disposed in contact with the nanosheets 344 of the first nanosheet FET element 341.

Notably, a height H1 of the troughs of the bottom S/D epitaxy 410 and the bottom S/D epitaxy 420 should exceed a height of hard masks disposed over the second nanosheet FET elements 323 and 343. This way, during a subsequent CMP process to be described below, the bottom S/D epitaxy 410 and the bottom S/D epitaxy 420 can be planarized to the height H1 without impacting the first and second stacked nanosheet FET structures 320 and 340.

As shown in FIG. 5, at a tertiary fabrication stage, a semiconductor device structure 501 is provided following the above-mentioned CMP process executed with respect to the semiconductor device structure 401 of FIG. 4. The semiconductor device structure 501 includes planarized upper surfaces 510 and 520 of the bottom S/D epitaxy 410 and the bottom S/D epitaxy 420, respectively, which are still higher than any portion of the first and second stacked nanosheet FET structures 320 and 340. The planarized upper surfaces 510 and 520 allow for subsequent recessions to be executed whereby the resulting structures will have a regular, predictable and controlled shape (i.e., such as a flat upper surface).

As shown in FIG. 6, at a fourth fabrication stage, a semiconductor device structure 601 is provided following the above-mentioned CMP and recession processes executed with respect to the semiconductor device structure 501 of FIG. 5. The semiconductor device structure 601 includes the bottom S/D epitaxy 410 and the bottom S/D epitaxy 420 having the regular, predictable and controlled shape with flat upper surfaces 610 and 620, respectively. The flat upper surface 610 can be coplanar with a portion of the dielectric material 322 and the flat upper surface 620 can be coplanar with a portion of the dielectric material 342.

As shown in FIG. 7, at a fifth fabrication stage, a semiconductor device structure 701 is provided following deposition of dielectric liner material and additional dielectric material 710 as well as formation of top S/D epitaxy 720 and 730 executed with respect to the semiconductor device structure 601 of FIG. 6. The dielectric liner material and the additional dielectric material 710 line exposed surfaces of the semiconductor device structure 601 but for the second nanosheet FET element 323 and the second nanosheet FET element 343. The top S/D epitaxy 720 can be grown from exposed portions of the nanosheets 326 and thus may have a shape differing from the shape of the bottom S/D epitaxy 410. The top S/D epitaxy 730 can be grown from exposed portions of the nanosheets 346 and thus may have a shape differing from the shape of the bottom S/D epitaxy 420.

With continued reference to FIGS. 6 and 7, the bottom S/D epitaxy 410, 420 can be rectangular and the top S/D epitaxy 720, 730 can be non-rectangular. In addition, a side 741, 742 of the bottom S/D epitaxy 410, 420 can be vertical and can define a vertical plane P1, P2 beyond which a side 751, 752 of the top S/D epitaxy 720, 730 protrudes.

In accordance with one or more embodiments, the bottom S/D epitaxy 410, 420 can be as wide or wider than a corresponding width of the nanosheets 324, 344 of the first nanosheet FET elements 321, 341. Also, as will be discussed below, the bottom S/D epitaxy 410, 420 can include the flat upper surface 610, 620 and a chamfered surface forming an obtuse angle with the flat upper surface 610, 620 and, in these or other cases, the semiconductor device structure can further include a wrap-around contact that is disposed in contact with the flat upper surface 610, 620 and the chamfered surface.

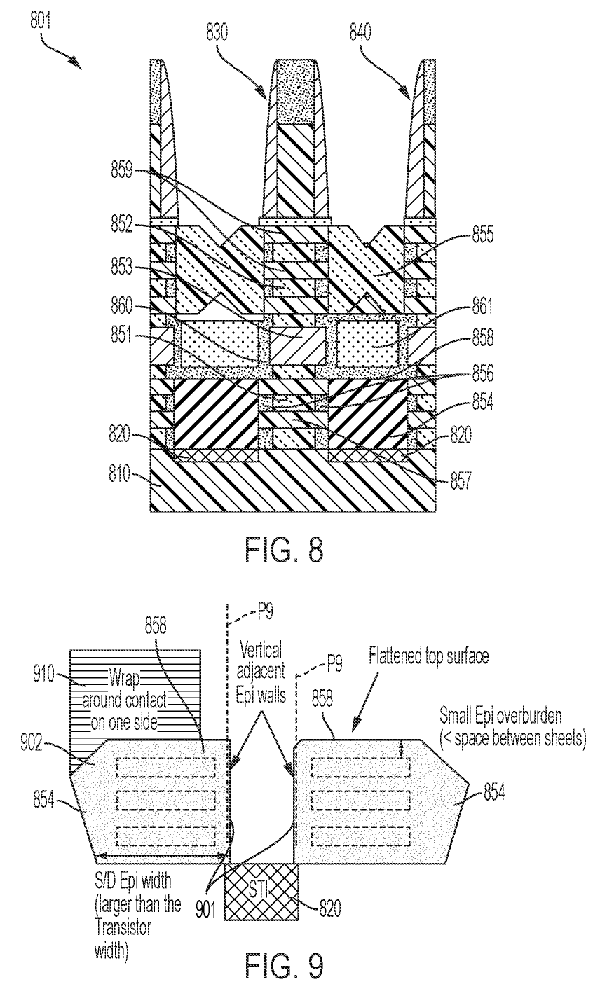

With reference to FIG. 8, a semiconductor device 801 is provided and can be fabricated generally as described above. The semiconductor device 801 includes a semiconductor substrate 810, shallow trench isolation (STI) 820 disposed in the semiconductor substrate 810, a first stacked nanosheet FET 830 and one or more second stacked nanosheet FETs 840 at opposite sides of the STI 820. The first stacked nanosheet FET 830 and the one or more second stacked nanosheet FETs 840 can each include a first nanosheet FET 851 disposed on the semiconductor substrate 810, a second nanosheet FET 852 stacked on the first nanosheet FET 851, dielectric material 853 vertically interposed between the first nanosheet FET 851 and the second nanosheet FET 852, bottom S/D epitaxy 854 and top S/D epitaxy 855 and inner spacers 856. The bottom S/D epitaxy 854 contacts portions of nanosheets 857 of the first nanosheet FET 851 that are exposed through the inner spacers 856. The bottom S/D epitaxy 854 is formed from depositional overgrowth, CMP and recession processes to thereby include a flat upper surface 858 that is coplanar with a portion of the dielectric material 853. The top S/D epitaxy 855 contacts nanosheets 859 of the second nanosheet FET 852 and is grown to have a shape differing from a shape of the bottom S/D epitaxy 854. Dielectric liner material 860 and additional dielectric material 861 can be disposed on the flat upper surface 858 of the bottom S/D epitaxy 854 of each of the first stacked nanosheet FET 830 and the one or more second stacked nanosheet FETs 840. For each of the first stacked nanosheet FET 830 and the one or more second stacked nanosheet FETs 840, the dielectric material 853, the dielectric liner material 860 and the additional dielectric material 861 can differ from one another.

In accordance with one or more embodiments, the bottom S/D epitaxy 854 can have a rectangular shape and the top S/D epitaxy 855 can be non-rectangular for each of the first stacked nanosheet FET 830 and the one or more second stacked nanosheet FETs 840.

With continued reference to FIG. 8 and with additional reference to FIG. 9, for each of the first stacked nanosheet FET 830 and the one or more second stacked nanosheet FETs 840, a side 901 of the bottom S/D epitaxy 854 can be vertical and can define a vertical plane P9 extending upwardly from the STI 820, the bottom S/D epitaxy 854 can be wider than a width of the nanosheets 857 of the first nanosheet FET 851, the bottom S/D epitaxy 854 can include the flat upper surface 858 and a chamfered surface 902 that is remote from the STI 820 and that forms an obtuse angle with the flat upper surface 858 and the semiconductor device 801 can further include a wrap-around contact 910. The wrap-around contact 910 can be disposed in contact with the flat upper surface 858 and the chamfered surface 902.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a semiconductor substrate;
a first nanosheet field effect transistor (FET) disposed on the semiconductor substrate;
a second nanosheet FET stacked on the first nanosheet FET;
dielectric material vertically interposed between the first nanosheet FET and the second nanosheet FET;
bottom source/drain (S/D) epitaxy contacting nanosheets of the first nanosheet FET, the bottom S/D epitaxy being formed from depositional overgrowth, chemical mechanical polishing (CMP) and recession processes and thereby comprising a flat upper surface coplanar with a portion of the dielectric material; and
top S/D epitaxy contacting nanosheets of the second nanosheet FET, the top S/D epitaxy being grown to have a shape differing from a shape of the bottom S/D epitaxy.

2. The semiconductor device according to claim 1, wherein the first nanosheet FET comprises inner spacers through which the nanosheets of the first nanosheet FET are exposed to contact the bottom S/D epitaxy.

3. The semiconductor device according to claim 1, further comprising dielectric liner material and additional dielectric material disposed on the flat upper surface of the bottom S/D epitaxy.

4. The semiconductor device according to claim 3, wherein the dielectric material, the dielectric liner material and the additional dielectric material differ from one another.

5. The semiconductor device according to claim 1, wherein the bottom S/D epitaxy is rectangular and the top S/D epitaxy is non-rectangular.

6. The semiconductor device according to claim 1, wherein:
a side of the bottom S/D epitaxy is vertical and defines a vertical plane, and
a side of the top S/D epitaxy, which corresponds to the side of the bottom S/D epitaxy, protrudes beyond the vertical plane.

7. The semiconductor device according to claim 1, wherein the bottom S/D epitaxy is wider than a width of the nanosheets of the first nanosheet FET.

8. The semiconductor device according to claim 1, wherein:
the bottom S/D epitaxy comprises the flat upper surface and a chamfered surface forming an obtuse angle with the flat upper surface, and
the semiconductor device further comprises a wrap-around contact disposed in contact with the flat upper surface and the chamfered surface.

9. A semiconductor device, comprising:
a semiconductor substrate;
shallow trench isolation (STI) disposed in the semiconductor substrate; and
first and second stacked nanosheet field effect transistors (FETs) at opposite sides of the STI and each comprising:
a first nanosheet FET disposed on the semiconductor substrate;
a second nanosheet FET stacked on the first nanosheet FET;
dielectric material vertically interposed between the first nanosheet FET and the second nanosheet FET;
bottom source/drain (S/D) epitaxy contacting nanosheets of the first nanosheet FET, the bottom S/D epitaxy being formed from depositional overgrowth, chemical mechanical polishing (CMP) and recession processes and thereby comprising a flat upper surface coplanar with a portion of the dielectric material; and top S/D epitaxy contacting nanosheets of the second nanosheet FET, the top S/D epitaxy being grown to have a shape differing from a shape of the bottom S/D epitaxy.

10. The semiconductor device according to claim 9, wherein the first nanosheet FET of each of the first and second stacked nanosheet FETs comprises inner spacers through which the nanosheets of the first nanosheet FET are exposed to contact the bottom S/D epitaxy.

11. The semiconductor device according to claim 9, further comprising dielectric liner material and additional dielectric material disposed on the flat upper surface of the bottom S/D epitaxy of each of the first and second stacked nanosheet FETs.

12. The semiconductor device according to claim 11, wherein, for each of the first and second stacked nanosheet FETs, the dielectric material, the dielectric liner material and the additional dielectric material differ from one another.

13. The semiconductor device according to claim 9, wherein the bottom S/D epitaxy is rectangular and the top S/D epitaxy is non-rectangular for each of the first and second stacked nanosheet FETs.

14. The semiconductor device according to claim 9, wherein, for each of the first and second stacked nanosheet FETs, a side of the bottom S/D epitaxy is vertical and defines a vertical plane extending upwardly from the STI.

15. The semiconductor device according to claim 9, wherein, for each of the first and second stacked nanosheet FETs, the bottom S/D epitaxy is wider than a width of the nanosheets of the first nanosheet FET.

16. The semiconductor device according to claim 9, wherein, for each of the first and second stacked nanosheet FETs:
the bottom S/D epitaxy comprises the flat upper surface and a chamfered surface remote from the STI and forming an obtuse angle with the flat upper surface, and the semiconductor device further comprises a wrap-around contact disposed in contact with the flat upper surface and the chamfered surface.

17. A method of fabricating a semiconductor device, the method comprising:
building a stacked nanosheet field effect transistor (FET) comprising a first nanosheet FET, a second nanosheet FET stacked on the first nanosheet FET, dielectric material vertically interposed between the first and second nanosheet FETs and inner spacers through which nanosheets of the first nanosheet FET are exposed;
forming bottom source/drain (S/D) epitaxy from depositional overgrowth to contact the nanosheets of the first nanosheet FET;
executing chemical mechanical polishing (CMP) of the bottom S/D epitaxy to a height which exceeds a height of a hard mask disposed over the second nanosheet FET;
recessing the bottom S/D epitaxy to comprise a flat upper surface coplanar with a portion of the dielectric material; and
forming top S/D epitaxy contacting nanosheets of the second nanosheet FET, the top S/D epitaxy being grown to have a shape differing from a shape of the bottom S/D epitaxy.

18. The method according to claim 17, wherein:
the method further comprises depositing dielectric liner material and additional dielectric material on the flat upper surface of the bottom S/D epitaxy, and
the dielectric material, the dielectric liner material and the additional dielectric material differ from one another.

19. The method according to claim 17, wherein the bottom S/D epitaxy is rectangular and the top S/D epitaxy is non-rectangular.

20. The semiconductor device according to claim 9, wherein:
the recessing of the bottom S/D epitaxy comprises forming the flat upper surface and a chamfered surface forming an obtuse angle with the flat upper surface, and
the method further comprises forming a wrap-around contact disposed in contact with the flat upper surface and the chamfered surface.
